(19) United States
(12) Patent Application Publication
(10) Pub. No.: US 2002/0195605 A1
(43) Pub. Date: Dec. 26, 2002

(54) Thin film resistor and manufacturing method thereof

(76) Inventor: Chi-Feng Huang, Pingtung Hsien (TW)

Correspondence Address: BIRCH STEWART KOLASCH & BIRCH, PO BOX 747, FALLS CHURCH, VA, 22040-0747, US

(21) Appl. No.: 09/927,399

(22) Filed: Aug. 13, 2001

(30) Foreign Application Priority Data
Jun. 26, 2001 (TW) 90115409

(51) Int. Cl. H01L 29/04; H01L 31/036

(52) U.S. Cl. 257/72

(57) ABSTRACT

A thin film resistor is provided. The resistor comprises a metal compound layer, and a resistor layer having a first doped region contacting the metal compound layer and a second doped region contacting the first doped region, wherein the first doped region is doped more heavily than the second doped region.

### BACKGROUND OF THE INVENTION

1. Field of the Invention

The present invention relates to a thin film resistor, particularly to a thin film resistor with high voltage linearity performance.

2. Description of the Prior Art

FIGS. 1A˜1E are diagrams showing a conventional method for manufacturing a thin film resistor.

First, as shown in FIG. 1A, a silicon substrate 10 is provided. An oxide layer 11, such as STI, is formed on the substrate 10, whereby active areas are defined on the substrate 10.

Second, as shown in FIG. 1B, a poly-silicon layer 12 is deposited on the oxide layer 11.

Third, as shown in FIG. 1C, the poly-silicon layer 12 is implanted with N/P type ions.

Fourth, as shown in FIG. 1D, a oxide layer 15 is deposited on the poly-silicon layer 12 and etched so that the poly-silicon layer 12 is uncovered. The uncovered polysilicon layer 12 has a silicide TiSi2 layer 13 formed thereon.

Finally, as shown in FIG. 1E, plugs 14 are formed on the TiSi₂ layer 13 and an oxide layer 16 is deposited. Thus, a thin film resistor layer composed of the doped poly-silicon layer 12 is formed between the plugs 14.

However, in a conventional thin film resistor, only one implementation step is applied to the poly-silicon layer, which results in a sharp junction in the poly-silicon layer. The sharp junction induces a Schottky Barrier and degrades the voltage linearity performance of the thin film resistor.

### SUMMARY OF THE INVENTION

Therefore, the object of the present invention is to provide a thin film resistor and a manufacturing method thereof, wherein the Schottky Barrier is eliminated.

The present invention provides a thin film resistor comprising a metal compound layer, and a resistor layer having a first doped region contacting the metal compound layer and a second doped region contacting the first-doped region, wherein the first doped region is doped more heavily than the second doped region.

The present invention further provides a method for manufacturing a thin film resistor. The method comprises the steps of providing a substrate, forming a resistor layer on the substrate, forming a first and a second doped regions contacting each other in the resistor layer, wherein the first doped region is doped more heavily than the second doped region, and forming a metal compound layer contacting the first doped region.

### BRIEF DESCRIPTION OF THE DRAWINGS

The following detailed description, given by way of example and not intended to limit the invention solely to the embodiments described herein, will best be understood in conjunction with the accompanying drawings, in which:

FIGS. 1A˜1E are diagrams showing a conventional method for manufacturing a thin film resistor.

FIG. 2A˜2E are diagrams showing a method for manufacturing a thin film resistor according to one embodiment of the invention.

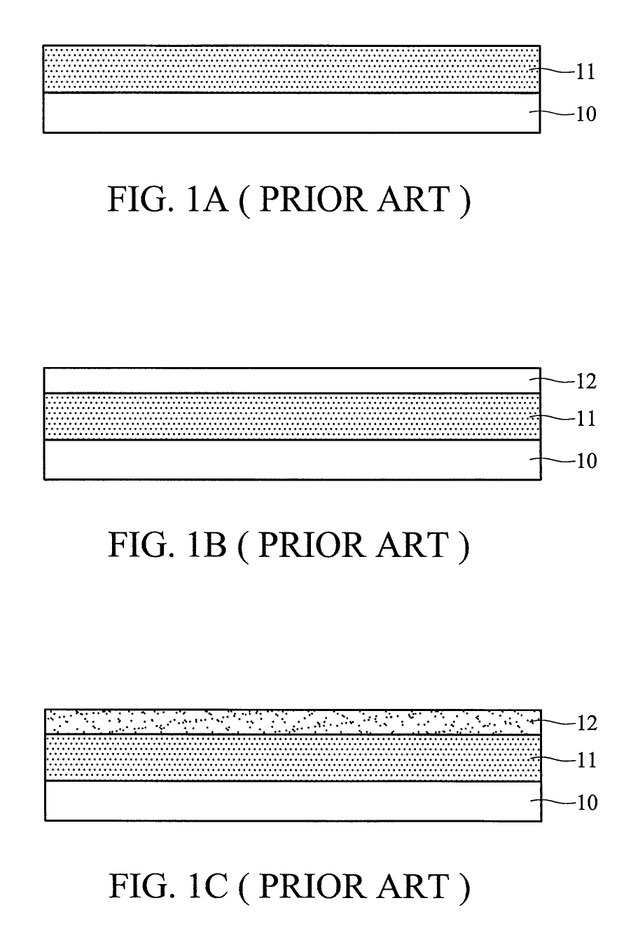

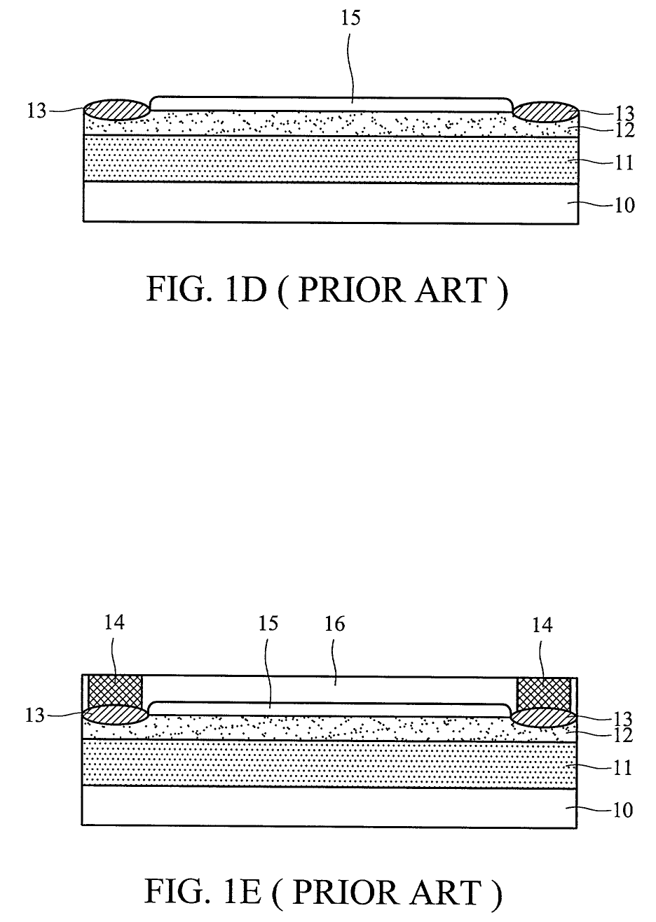

### DETAILED DESCRIPTION OF THE INVENTION

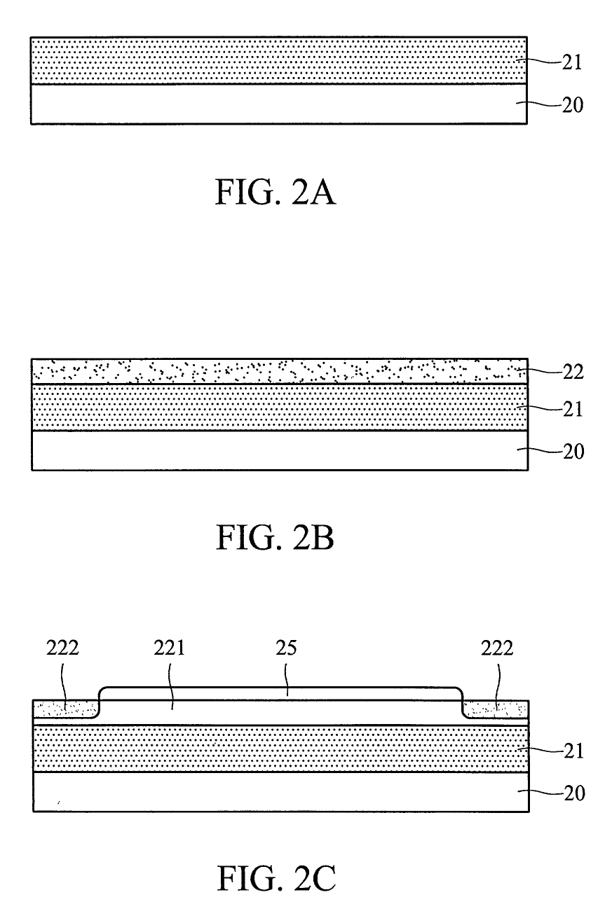

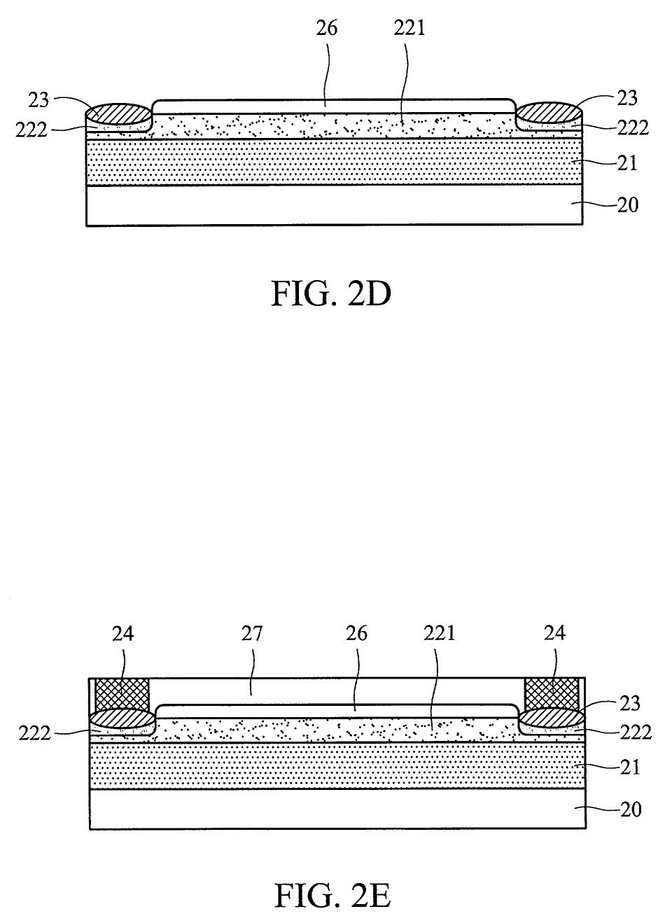

FIG. 2A˜2E are diagrams showing a method for manufacturing a thin film resistor according to one embodiment of the invention.

First, as shown in FIG. 2A, a silicon substrate 20 is provided. An oxide layer 21, such as STI, is formed on the substrate 20, whereby active areas are defined on the substrate 20.

Second, as shown in FIG. 2B, a poly-silicon layer 22 is deposited on the oxide layer 21. The poly-silicon layer 22 is implanted with N/P type ions for the first time.

Third, as shown in FIG. 2C, a photoresist layer 25 is deposited on the poly-silicon layer 22. The photoresist layer 25 is exposed and developed so that the poly-silicon layer 22 is uncovered. The uncovered poly-silicon layer 22 is implanted with N/P type ions for the second time at a concentration higher than that for the first time. Thus, a doped region 221 and a doped region 222 heavier than the region 221 are formed.

Fourth, as shown in FIG. 2D, the photoresist layer 25 is removed and an oxide layer 26 is deposited on the polysilicon layer 22. The oxide layer 26 is etched so that the poly-silicon layer 22 is uncovered. The uncovered polysilicon layer 22 has a silicide TiSi2 layer 23 formed thereon.

Finally, as shown in FIG. 2E, plugs 24 are formed on the TiSi₂ layer 23 and an oxide layer 27 is deposited. Thus, a thin film resistor layer composed of the poly-silicon layer 22 having doped regions at different concentrations is formed between the plugs 24.

Accordingly, the thin film resistor of this embodiment of the invention comprises the substrate 20, the isolation (oxide) layer 21, the poly-silicon layer 22 on the isolation layer 21, the doped regions 221 and 222 contacting each other, the TiSi₂ layer 23, the plugs 24 contacting the TiSi₂ layer 23, and the oxide layers 26 and 27. The doped region 222 is doped more heavily than the doped region 221 so that the Schottky Barrier is eliminated.

In conclusion, two implementation steps are applied to the poly-silicon layer so that the regions of the polysilicon layer that will receive a silicide layer have a more heavily doped region. Thus, the Schottky Barrier is eliminated and there is a ohmic contact between the silicide (TiSi₂) layer and the poly-silicon layer, whereby the voltage linearity performance of the thin film resistor is improved.

While the invention has been described by way of example and in terms of the preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A thin film resistor comprising:
a metal compound layer; and
a resistor layer having a first doped region contacting the metal compound layer and a second doped region contacting the first doped region, wherein the first doped region is doped more heavily than the second doped region.

2. The resistor as claimed in claim 1, further comprising a substrate having an isolation layer on which the resistor layer is formed.

3. The resistor as claimed in claim 1, further comprising a plug connected to the metal compound layer.

4. The resistor as claimed in claim 1, wherein the resistor layer is a thin film poly silicon layer.

5. The resistor as claimed in claim 1, wherein the metal compound layer is a TiSi₂ layer.

6. The resistor as claimed in claim 1, wherein the first and second doped regions are N-type doped regions.

7. The resistor as claimed in claim 1, wherein the first and second doped regions are P-type doped regions.

8. A method for manufacturing a thin film resistor comprising the steps of:
providing a substrate;
forming a resistor layer on the substrate;
forming first and second doped regions contacting each other in the resistor layer, wherein the first doped region is doped more heavily than the second doped region; and
forming a metal compound layer contacting the first doped region.

9. The method as claimed in claim 8, wherein the substrate has an isolation layer on which the resistor layer is formed.

10. The method as claimed in claim 8, further comprising the step of forming a plug connected to the metal compound layer.

11. The method as claimed in claim 8, wherein the resistor layer is a thin film poly silicon layer.

12. The method as claimed in claim 8, wherein the metal compound layer is a TiSi₂ layer.

13. The method as claimed in claim 8, wherein the first and second doped regions are N-type doped regions.

14. The method as claimed in claim 8, wherein the first and second doped regions are P-type doped regions.
